(19) United States
(12) Patent Application Publication
(10) Pub. No.: US 2009/0114957 A1
(43) Pub. Date: May 7, 2009

(54) SEMICONDUCTOR DEVICE AND METHOD OF MANUFACTURING THE SAME

(76) Inventor: Mun-Sub Hwang, Yuseong-gu (KR)

Correspondence Address: SHERR & VAUGHN, PLLC, 620 HERNDON PARKWAY, SUITE 200, HERNDON, VA, 20170, US

(21) Appl. No.: 12/263,482

(22) Filed: Nov. 2, 2008

(30) Foreign Application Priority Data
Nov. 5, 2007 (KR) 10-2007-0112058

(51) Int. Cl. H01L 21/336; H01L 29/78

(52) U.S. Cl. 257/288; 438/301; 257/E21.409; 257/E29.255

(57) ABSTRACT

A semiconductor device and a method thereof that maximizes DC and AC parameter properties of a MOS transistor having a buried channel. The device includes a semiconductor substrate having a device separation film, a gate pattern formed over the semiconductor substrate, a well region formed in the semiconductor substrate, the well region including a first doped region formed at a first predetermined depth, a second doped region formed at a second predetermined depth and a third doped region formed at a third predetermined depth, trenches formed at a source/drain region around the gate pattern, and a source/drain formed in the trenches. In accordance with embodiments, the first predetermined depth is lower than the second and third predetermined depths and the third predetermined depth is greater than the second predetermined depth.

The present application claims priority under 35 U.S.C. §119 to Korean Patent Application No. 10-2007-0112058 (filed on Nov. 5, 2007), which is hereby incorporated by reference in its entirety.

### BACKGROUND

A semiconductor device exhibits not only DC parameters (threshold voltage, drive current, leakage current, etc) but also AC parameters (transconductance, etc), the importance of which is being emphasized. In particular, the above-mentioned parameters must be essentially satisfied when implementing a system-on-chip (SoC) using a process technology for a CMOS semiconductor, which is the next-generation device. Generally, electron mobility is approximately twice as faster as hole mobility. Consequently, the operation speed and the DC and AC parameter properties of a NMOS device are better than those of a PMOS device.

However, not only the properties of the NMOS semiconductor device but also the properties of the PMOS semiconductor device must be accompanied such that a semiconductor device manufacture by the CMOS semiconductor process technology can perfectly perform its duty. For this reason, various research has been carried out to improve the properties of the PMOS semiconductor device. For example, a buried transistor has been used as a method of improving the properties of the PMOS semiconductor device. However, the implementation of the buried transistor is not easy, with the result that the buried transistor is not implemented in CMOS semiconductor process technology.

Generally, a channel of the MOS transistor is formed at the surface of a silicon substrate. While forming an active region using an ion implantation process, however, the surface of the silicon substrate is damaged, with the result that one or more vacancies are formed at the surface of the silicon substrate, i.e., the lattice structure is changed, which effects the passage of a carrier. This effect leads to the reduction of drive current. Also, transconductance (hereinafter, referred to as Gₘ), which is an AC parameter property, decreases due to the obstruction in passage of the carrier, since Gₘ is proportional to the mobility as represented by the following equation.

$${G}_{m} = \frac{{μ}_{n} {C}_{ox} W}{L} ( {V}_{G} - {V}_{T} )$$

In a PMOS manufacturing method, therefore, the channel is formed at the damaged surface of the silicon substrate, which may result in deterioration of the DC and AC parameter properties of the PMOS semiconductor device.

### SUMMARY

Embodiments relate to a semiconductor device and a method of manufacturing the same that maximizes DC and AC parameter properties of a MOS transistor having a buried channel.

Embodiments relate to a method of manufacturing a PMOS having a buried channel that may include at least one of the following: implanting ions into a semiconductor substrate having a device separation film in stages to form an N-type well; depositing a gate isolation film and a gate conduction film; performing a photolithography/etching process for forming a gate electrode to pattern the gate conduction film; and performing a photolithography process for opening a source/drain region and partially etching the source/drain region. In accordance with embodiments, the implanting of ions may include implanting phosphorous ions using an energy in a range between approximately 400 to 600 KeV, implanting phosphorous ions using an energy in a range between approximately 200 to 300 KeV, and implanting arsenic ions using an energy in a range between approximately 100 to 200 KeV.

Embodiments relate to a method that may include at least one of the following: forming a device isolation layer in a semiconductor substrate; and then sequentially forming doped regions at different depths in the semiconductor substrate by implanting impurity ions in a semiconductor substrate; and then sequentially forming a gate isolation film and a gate conduction film over the semiconductor substrate including the three doped regions; and then forming a gate pattern by patterning the gate isolation film and the gate conduction film; and then forming a source-drain in the semiconductor substrate by etching a portion of the semiconductor substrate around the gate pattern at a predetermined depth and implanting impurity ions into the portion of the semiconductor substrate.

Embodiments relate to a method that may include at least one of the following: forming a first doped region at a first predetermined depth in the semiconductor substrate using a first predetermined ion implantation energy; and then forming a second doped region at a second predetermined depth in the semiconductor substrate using a second predetermined ion implantation energy; and then forming a third doped region at a third predetermined depth in the semiconductor substrate using a third predetermined ion implantation energy; and then forming a gate pattern over the semiconductor substrate including the first, second and third doped regions; and then forming a source-drain in the semiconductor substrate by etching a portion of the semiconductor substrate including a portion of the third doped region. In accordance with embodiments, the first predetermined depth is lower than the second and third predetermined depths, the first predetermined ion implantation energy is greater than the second and third predetermined ion implantation energies, the third predetermined depth is greater than the second predetermined depth and the third predetermined ion implantation energy is lower than the second predetermined ion implantation energy.

Embodiments relate to a buried-channel PMOS that may include at least one of the following: an N-type well including a first doped region formed by implanting phosphorous ions into a semiconductor substrate having a device separation film using an energy in a range between approximately 400 to 600 KeV; a second doped region formed by implanting phosphorous ions into the semiconductor substrate using an energy in a range between approximately 200 to 300 KeV; and a third doped region formed by implanting arsenic ions into the semiconductor substrate using an energy in a range between approximately 100 to 200 KeV; a gate isolation film formed on and/or over the semiconductor substrate having the N-type well formed therein; a gate electrode formed on and/or over the gate isolation film; and a source/drain formed by etching an active region to a depth at which the third doped region is formed.

Embodiments relate to a device that may include at least one of the following: a semiconductor substrate having a device separation film; a gate pattern formed over the semiconductor substrate; a well region formed in the semiconductor substrate, the well region including a first doped region formed at a first predetermined depth, a second doped region formed at a second predetermined depth and a third doped region formed at a third predetermined depth; trenches formed at a source/drain region around the gate pattern; and a source/drain formed in the trenches. In accordance with embodiments, the first predetermined depth is lower than the second and third predetermined depths and the third predetermined depth is greater than the second predetermined depth.

### DRAWINGS

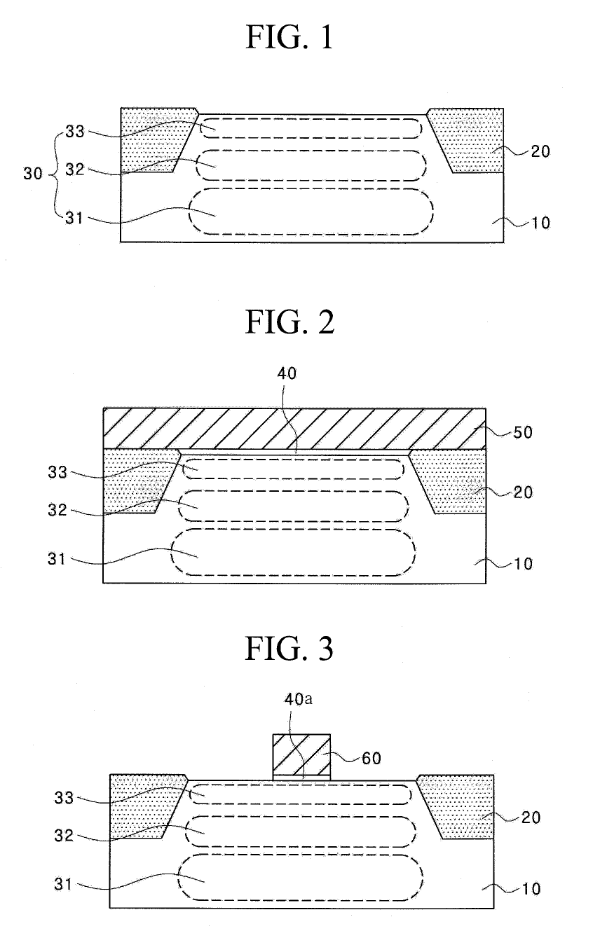

Example FIGS. 1 to 5 illustrate semiconductor devices and a method of manufacturing a semiconductor device in accordance with embodiments.

### DESCRIPTION

Example FIGS. 1 to 4 are process sectional views illustrating a method of manufacturing a semiconductor device such as a PMOS having as buried channel in accordance with embodiments. As illustrated in example FIG. 1, a field oxide film 20 to define an active region and an inter-device separation region is formed in a semiconductor substrate 10. The field oxide film 20 is a device separation film. The field oxide film 20 may be formed by shallow trench isolation (STI) or local oxidation of silicon (LOCOS). An ion implantation mask is patterned on and/or over the semiconductor substrate 10 having the field oxidation film 20. An ion implantation process is performed in stages to form a multi-level N-type well 30 at the active region. The ion implantation process to form the N-type well 30 is carried out by implanting N-type impurity ions into the semiconductor device 10 in stages using different ion implantation energies. Specifically, the N-type well 30 includes first doped region 31, second doped region 32 and third doped region 33 formed at different depths in the substrate 10. The lowermost first doped region 31 is formed by implanting phosphorous ions using the highest ion implantation energy (e.g., in a range between approximately 400 to 600 KeV). Subsequently, the second doped region 32 is formed on and/or over the first doped region 31 by implanting phosphorous ions using a second ion implantation energy (e.g., in a range between approximately 200 to 300 KeV) lower than the first ion implantation energy used to form the first doped region 31. Subsequently, the third doped region 33 is formed on and/or over the second doped region 32 by implanting arsenic ions using a third and lowest ion implantation energy (e.g., in a range between approximately 100 to 200 KeV). A BF₂ ion implantation process may also be performed with the ion implantation process in order to control the threshold voltage of a channel.

As illustrated in example FIG. 2, a gate isolation film 40 and a gate conduction film 50 are sequentially formed on and/or over the semiconductor device 10 including the N-type well 30 formed therein. The gate isolation film 40 is formed is formed between neighboring ones of the field oxide films 20 by depositing a silicon oxide film (SiO₂) on and/or over the semiconductor substrate 10 using thermal oxidation. The gate conduction film 50 is formed by depositing a poly silicon film on the silicon oxide film.

As illustrated in example FIG. 3, a photolithography/etching process is performed with respect to the gate isolation film 40 and the gate conduction film 50 to pattern the gate isolation film 40 and the gate conduction film 50 such that a gate pattern including a gate isolation film pattern 40a and a gate electrode 60 are formed. The gate pattern is formed by reactive ion etching.

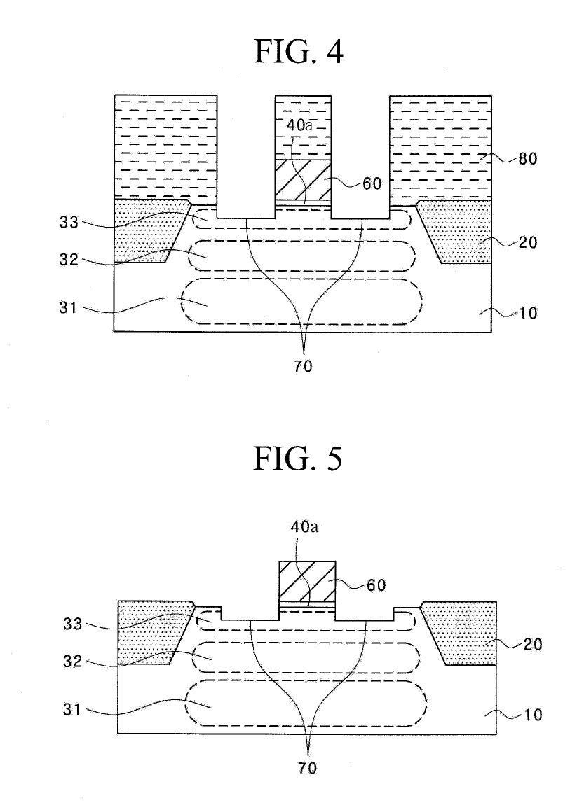

As illustrated in example FIG. 4, a photosensitive film is formed on and/or over the entire surface of the semiconductor substrate 10 having the gate pattern formed thereon, and a photolithography/etching process is performed with respect to the photosensitive film to form a photosensitive film pattern 80 necessary to open a source/drain region 70. The photosensitive film pattern 80 is preferably patterned to mask the edge of the device separation film 20 and the periphery of the gate pattern. Subsequently, an etching process using the photosensitive film pattern 80 is performed to partially etch a portion of the semiconductor substrate 10 to a predetermined depth. Specifically, a portion of the semiconductor substrate corresponding to the source/drain region around the gate pattern is partially etched to the predetermined depth. Trenches 70 are formed at opposite sides of the gate pattern around the gate pattern by the partial etching. The trenches 70 are formed by reactive ion etching. The etching depth to form the trenches 70 is preferably decided such that the semiconductor substrate 10 is partially etched to the depth of the channel region. More preferably, the trenches 70 are formed by partially etching the semiconductor substrate 10 within the depth of the third doped region 33 in consideration of a doped profile at the part where the channel is formed. Subsequently, impurity ions are implanted into the partially etched trenches 70 to form a source/drain at the opposite sides of the gate pattern. Processes of forming a sidewall of the gate pattern and a process to form a spacer may be additionally performed. In accordance with embodiments, a PMOS transistor having a buried channel is completed through the process illustrated in example FIGS. 1 to 4.

Example FIG. 5 is a sectional view illustrating the structure of a semiconductor device such as a PMOS transistor having a buried channel in accordance with embodiments. As illustrated in example FIG. 5, the semiconductor device includes a semiconductor substrate 10 having a field oxide film 20 as a device separation film, an N-type well 30, a gate pattern including patterns gate insulating film 40a and gate electrode 60, trenches 70, and a source/drain. The N-type well 30 is formed in the semiconductor substrate 10. The N-type well 30 includes a first doped region 31, a second doped region 32, and a third doped region 33 which are sequentially formed in the semiconductor substrate 10 from the bottom. The doped regions 31, 32, 33 are formed by ion implantation processes using different ion implantation energies. Consequently, the depths at which the doped regions 31, 32, 33 are formed are different from one another. For example, the first doped region 31 is formed in the semiconductor substrate 10 having the device separation film 20 by implanting phosphorous ions using an energy in a range between approximately 400 to 600 KeV. The second doped region 32 is formed by implanting phosphorous ions using an energy in a range between approximately 200 to 300 KeV. The third doped region 33 is formed by implanting arsenic ions using an energy in a range between approximately 100 to 200 KeV. Consequently, the first doped region 31 and the second doped region 32 are phosphorous ion implanted regions, and the third doped region 33 is an arsenic ion implanted region.

The gate patterns 40a and 60 are formed by patterning a gate isolation film 40 and a gate conduction film 50 sequentially formed on and/or over the semiconductor substrate 10. The gate isolation film 40 may be a silicon oxide film, and the gate conduction film 50 may be a polysilicon film formed on and/or over the silicon oxide film. The trenches 70 are formed at the source/drain region around the gate patterns 40a and 60. The trenches 70 are formed by partially etching a portion of the semiconductor corresponding to the source/drain region around the gate patterns 40a and 60. The trenches 70 may be formed to the depth of a channel region formed in the semiconductor substrate. Also, the trenches 70 may be formed within the depth of the uppermost doped region among the doped regions 31, 32, 33, i.e., the third doped region 33. A source/drain is formed by implanting impurity ions into the trenches 70.

In the PMOS transistor having the buried channel in accordance with embodiments, the silicon quality of the region where the channel is formed is better than other silicon quality by using the N-type well 30. As a result, drive current is maximized while leakage current is minimized in the DC parameter aspect of the semiconductor device. Also, the carrier mobility is maximized, whereby the RC delay of the device is minimized, and therefore, the operation speed is maximized. On the other hand, the Gₘ value is maximized in the AC parameter aspect, and therefore, the DC gain is also maximized. Accordingly, a PMOS transistor having a buried channel may be manufactured in accordance with embodiments having maximized DC and AC parameter properties.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a device isolation layer in a semiconductor substrate; and then
sequentially forming a well region having doped regions at different depths in the semiconductor substrate by implanting impurity ions in a semiconductor substrate; and then
sequentially forming a gate isolation film and a gate conduction film over the semiconductor substrate including the three doped regions; and then
forming a gate pattern by patterning the gate isolation film and the gate conduction film; and then
forming a source-drain in the semiconductor substrate by etching a portion of the semiconductor substrate around the gate pattern at a predetermined depth and implanting impurity ions into the portion of the semiconductor substrate.

2. The method of claim 1, wherein the doped regions are formed by implanting N-type impurities into the semiconductor substrate using different ion implantation energies.

3. The method of claim 2, wherein a lowermost one of the doped regions has the greatest ion implantation energy and an uppermost one of the doped regions has the least ion implantation energy.

4. The method of claim 1, wherein two of the doped regions are formed by implanting phosphorous ions in the semiconductor substrate using different ion implantation energies.

5. The method of claim 5, wherein a third doped region is formed by implanting arsenic ions in the semiconductor substrate.

6. The method of claim 1, wherein the gate isolation film is formed by depositing a silicon oxide film (SiO₂) over the semiconductor substrate using thermal oxidation.

7. The method of claim 1, wherein the gate conduction film is formed by depositing a polysilicon film over the gate isolation film.

8. The method of claim 1, wherein forming the source/drain comprises etching the semiconductor within an uppermost one of the doped regions.

9. A method comprising:
forming a first doped region at a first predetermined depth in the semiconductor substrate using a first predetermined ion implantation energy; and then
forming a second doped region at a second predetermined depth in the semiconductor substrate using a second predetermined ion implantation energy; and then
forming a third doped region at a third predetermined depth in the semiconductor substrate using a third predetermined ion implantation energy; and then
forming a gate pattern over the semiconductor substrate including the first, second and third doped regions; and then
forming a source-drain in the semiconductor substrate by etching a portion of the semiconductor substrate including a portion of the third doped region,
wherein the first predetermined depth is lower than the second and third predetermined depths, the first predetermined ion implantation energy is greater than the second and third predetermined ion implantation energies, the third predetermined depth is greater than the second predetermined depth and the third predetermined ion implantation energy is lower than the second predetermined ion implantation energy.

10. The method of claim 9, wherein forming the first doped region comprises implanting N-type impurities in the semiconductor substrate using the first predetermined ion implantation energy in a range between approximately 400 to 600 KeV.

11. The method according to claim 9, wherein forming the second doped region comprises implanting N-type impurities in the semiconductor substrate using the second predetermined ion implantation energy in a range between approximately 200 to 300 KeV.

12. The method according to claim 9, wherein forming the third doped region comprises implanting N-type impurities in the semiconductor substrate using the third predetermined ion implantation energy in a range between approximately 100 to 200 KeV.

13. The method of claim 6, wherein the first and second doped regions are formed by implanting phosphorous ions in the semiconductor substrate and the third doped region is formed by implanting arsenic ions in the semiconductor substrate.

14. The method of claim 6, wherein forming the gate patterns comprises:
sequentially forming a gate isolation film and a gate conduction film over the semiconductor substrate; and then
patterning the gate isolation film and the gate conduction film.

15. The method of claim 14, wherein the gate isolation film is formed by depositing an oxide film over the semiconductor substrate.

16. The method of claim 15, wherein the oxide film comprises silicon oxide (SiO₂).

17. The method of claim 15, wherein the oxide film is formed using thermal oxidation.

18. A device comprising:
a semiconductor substrate having a device separation film;
a gate pattern formed over the semiconductor substrate;
a well region formed in the semiconductor substrate, the well region including a first doped region formed at a first predetermined depth, a second doped region formed at a second predetermined depth and a third doped region formed at a third predetermined depth;
trenches formed at a source/drain region around the gate pattern; and
a source/drain formed in the trenches,
wherein the first predetermined depth is lower than the second and third predetermined depths and the third predetermined depth is greater than the second predetermined depth.

19. The device of claim 18, wherein the gate pattern comprises a silicon oxide film (SiO₂) formed over the semiconductor substrate and a polysilicon film formed over the silicon oxide film.

20. The device of claim 18, wherein the first and second doped regions are formed of phosphorous ions and the third doped region is formed of arsenic ions.
